(19) United States
(12) Patent Application Publication
(10) Pub. No.: US 2025/0224309 A1
(43) Pub. Date: Jul. 10, 2025

(54) ROADWAY SIMULATOR WITH LIMITED ENERGIZED OPERATING STATE

(71) Applicant: Illinois Tool Works Inc., Glenview, IL (US)

(72) Inventors: Victor Senft, Edina, MN (US); David James Melcher, Mendota Heights, MN (US); Marlin Jay Sunderman, Edina, MN (US); Rick Lee Zieman, Minnetrista, MN (US); Scott Loren Staup, Foreston, MN (US)

(21) Appl. No.: 19/012,487

(22) Filed: Jan. 7, 2025

Related U.S. Application Data
(60) Provisional application No. 63/619,627, filed on Jan. 10, 2024.

(51) Int. Cl. G01M 17/007

(52) U.S. Cl. CPC G01M 17/0072

(57) ABSTRACT

A roadway simulator comprises: a rotatable assembly for rotating a wheel and a restraint couplable to a vehicle. The restraint includes a first actuator to position an end of the restraint proximate the vehicle and/or a second actuator to couple the restraint to the vehicle. A controller operates the simulator in a lockout state wherein power is isolated from the simulator that inhibits operation for conducting a test including isolating electrical power from a rotatable drive assembly for the rotatable assembly and an actuator drive assembly for the first actuator and/or the second actuator. The controller operates the simulator in a limited energized state wherein testing of the vehicle is inhibited due to continued isolation of electrical power to the rotatable drive assembly and wherein electrical power is restored to the actuator drive assembly for the first actuator and/or the second actuator.

### CROSS-REFERENCE TO RELATED APPLICATION

The present application is based on and claims the benefit of U.S. provisional patent application Ser. No. 63/619,627, filed Jan. 10, 2024, the content of which is hereby incorporated by reference in its entirety.

### BACKGROUND

The discussion below is merely provided for general background information and is not intended to be used as an aid in determining the scope of the claimed subject matter.

Aspects of the present invention relate to equipment and methods used during laboratory testing of bodies moving over surfaces such as but not limited to all types of vehicles traveling on a roadway.

Referring to vehicles such as automobiles by way of example, the use of simulated roadways has become important in the development of vehicle designs. These roadway simulators generally comprise one or more individual endless belts that are mounted below the vehicle, engaging one or more wheels, and/or positioned below other body panels of the vehicle. The belts are driven to simulate driving the vehicle over a road. Some roadway simulators are disposed in wind tunnels so as to measure aerodynamic characteristics.

The vehicle is typically restrained with respect to the simulated roadways through one or more restraints that restrains the vehicle from movement in longitudinal direction (fore and aft), in lateral direction (side-to-side) and/or in yaw (steering motion). Commonly, the vehicle restraints are passive restraints which do not affect the vehicle's dynamics, but which can be used for measuring loads if desired in the different directions of restraint.

### SUMMARY

This Summary and the Abstract herein are provided to introduce a selection of concepts in a simplified form that are further described below in the Detailed Description. This Summary and the Abstract are not intended to identify key features or essential features of the claimed subject matter, nor are they intended to be used as an aid in determining the scope of the claimed subject matter. The claimed subject matter is not limited to implementations that solve any or all disadvantages noted in the background.

An aspect of the present invention is a method for testing a vehicle on a roadway simulator having at least one rotatable assembly for rotating at least one wheel of the vehicle, the method comprising: positioning the vehicle on the at least one rotatable assembly; coupling a restraint to the vehicle so as to limit longitudinal and/or lateral movement of the vehicle on the at least one rotatable assembly, wherein coupling includes controlling a first actuator to position an end of the restraint proximate a portion of the vehicle and/or controlling a second actuator to couple the restraint to the portion of the vehicle; driving the at least one rotatable assembly to rotate the at least one wheel on the vehicle; configuring the roadway simulator in a lockout state wherein power is isolated from roadway simulator that inhibits operation for conducting a test including isolating electrical power from a rotatable drive assembly for the at least one rotatable assembly and for isolating electrical power from an actuator drive assembly for the first actuator and/or the second actuator; configuring the roadway simulator in a limited energized state wherein testing of the vehicle is inhibited due to continued isolation of electrical power to the rotatable drive assembly and wherein electrical power is restored to the actuator drive assembly for the first actuator and/or the second actuator; and controlling the first actuator to position the end of the restraint remote from the vehicle to allow the vehicle to be removed the at least one rotatable assembly and/or controlling the second actuator to decouple the restraint from the portion of the vehicle.

Implementations may include one or more of the following features. The roadway simulator can include a designated control for configuring the roadway simulator in the limited energized state, and where configuring the roadway simulator in the limited energization state includes providing a control signal from the designated control to energize circuitry for the first and/or second actuator. In one embodiment, the designated control can be remote from a user interface for operating the roadway simulator to perform the test of the vehicle by controlling the at least one rotatable assembly. In another embodiment, the designated control can be part of a user interface for operating the roadway simulator to perform the test of the vehicle by controlling the at least one rotatable assembly. If desired, the designated control is not configured to operate a switch that provides electrical power to the rotatable drive assembly.

Providing the control signal can include providing a control signal to a first controlled switch to operate the first controlled switch to provide electrical power to the actuator drive assembly for the first actuator and/or the second actuator. The actuator drive assembly may include an actuator electrical power supply providing power to the first actuator and/or the second actuator and an actuator control module connected to the actuator electrical power supply and configured to control operation of the actuator electrical power supply.

A power supply switch can selectively provide electrical power to the actuator electrical power supply, and a control module switch selectively provides electrical power to the actuator control module, and where providing the control signal operates the power supply switch to provide electrical power to the actuator electrical power supply, and operates the control module switch to provide electrical power to the actuator control module. The power supply switch can selectively provide electrical power to another portion of the roadway simulator different than the actuator electrical power supply, the another portion of the roadway simulator having another control module different than the actuator control module, where providing the control signal does not provide electrical power to the another control module.

The roadway simulator may include a positioner for controlling a position of an element of the roadway simulator, and where configuring the roadway simulator in the lockout state may include isolating electrical power to a positioner drive assembly of the positioner, and where configuring the roadway simulator in the limited energized state, may include restoring electrical power to the positioner drive assembly. The positioner positions the element in a selected position to allow removal of the vehicle from the roadway simulator.

The roadway simulator may include a turntable supporting the vehicle in selected angular positions, and the positioner drive assembly rotates the turntable. The positioner is coupled to the at least one rotatable assembly. The positioner drive assembly may include a positioner electrical power supply providing power to the positioner and a positioner control module connected to the positioner electrical power supply and configured to control operation of the positioner electrical power supply.

A positioner power supply switch can selectively provide electrical power to the positioner electrical power supply, and a positioner control module switch selectively provides electrical power to the positioner control module, and where providing the control signal operates the positioner power supply switch to provide electrical power to the positioner electrical power supply, and operates the positioner control module switch to provide electrical power to the positioner control module.

Coupling the restraint to the vehicle may include coupling the restraint to a side portion of the vehicle. The first actuator adjusts a position of the end of the restraint, and the second actuator operates a coupler that couples the restraint to the vehicle. Coupling the restraint to the vehicle may include coupling the restraint to an end portion of the vehicle. Coupling the restraint to the vehicle may include coupling the restraint to an upper portion of the vehicle.

The at least one rotatable assembly may include a single belt supporting and rotatably driving each wheel of the vehicle. The at least one rotatable assembly may include a plurality of separate rotatable assemblies, each separate rotatable assembly rotatably driving at least one wheel of the vehicle. The at least one rotatable assembly may include a plurality of separate rotatable assemblies, each separate rotatable assembly rotatably driving one wheel of the vehicle.

Another aspect of the present invention is a roadway simulator comprising: at least one rotatable assembly for rotating at least one wheel of the vehicle; a restraint couplable to a vehicle so as to limit longitudinal and/or lateral movement of the vehicle on the at least one rotatable assembly, wherein the restraint includes a first actuator to position an end of the restraint proximate a portion of the vehicle and/or a second actuator to couple the restraint to the portion of the vehicle; a controller operable to configure the roadway simulator in a lockout state wherein power is isolated from roadway simulator that inhibits operation for conducting a test including isolating electrical power from a rotatable drive assembly for the at least one rotatable assembly and for isolating electrical power from an actuator drive assembly for the first actuator and/or the second actuator, and operable to configure the roadway simulator in a limited energized state wherein testing of the vehicle is inhibited due to continued isolation of electrical power to the rotatable drive assembly and wherein electrical power is restored to the actuator drive assembly for the first actuator and/or the second actuator.

Implementations may include one or more of the following features. The roadway simulator may include a designated control for configuring the roadway simulator in the limited energized state, and where the designated control provides a control signal to energize circuitry for the first and/or second actuator. In one embodiment, the designated control can be remote from a user interface for operating the roadway simulator to perform the test of the vehicle by controlling the at least one rotatable assembly. In another embodiment, the designated control is part of a user interface for operating the roadway simulator to perform the test of the vehicle by controlling the at least one rotatable assembly.

### BRIEF DESCRIPTION OF THE DRAWINGS

FIG. 1 is a perspective view of a first embodiment of a vehicle restraint system.

FIG. 2 is an enlarged perspective view of a portion of the first embodiment;

FIG. 3 is a front elevational view of the first embodiment;

FIG. 4 is a perspective view of a second embodiment of a vehicle restraint system.

FIG. 5 is a front elevational view of a portion of the second embodiment;

FIG. 6 is schematic diagram of electrical cabinetry for the simulator; and

FIG. 7 is a method for operating the vehicle simulator.

### DETAILED DESCRIPTION OF ILLUSTRATIVE EMBODIMENTS

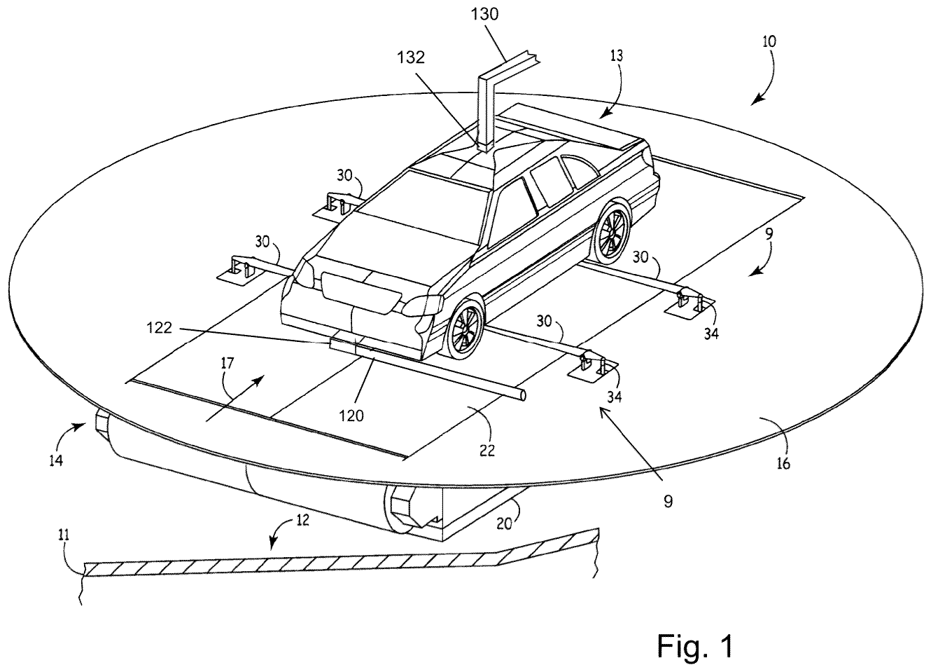

Referring to FIG. 1, an exemplary vehicle restraint 9 and roadway simulator 10 having one or more aspects of the invention is illustrated. In the embodiment illustrated, a vehicle 13 is an automobile; however, it should be understood that this is but one example of a vehicle that can benefit from aspects of the present invention. For that matter, any type of test article restrained relative to a moving surface provided by an endless belt or drums can benefit from one or more aspects of the present invention; however, particular advantages are realized for a vehicle moving over a roadway surface.

In the embodiment illustrated, the simulator 10 includes a support base 11, which generally can comprise a large concrete structure having a pit indicated generally at 12 in which the main roadway mechanisms 14 are mounted so that the vehicle 13 to be tested is at about the level of the surface surrounding the pit 12. In many instances, the simulator 10 forms part of a wind tunnel having a fan, not shown, but represented by arrow 17. The vehicle 13 and the main roadway mechanism 14 can include a platform 16, which, in the embodiment illustrated, is a turntable that allows the vehicle 13 to be positioned selectively with respect to the air flow 17 generated by the fan.

The platform 16 and the main roadway mechanisms 14, although not necessary, can be mounted on a balance assembly, schematically illustrated at 20, which can measure various forces upon the vehicle 13. Such balance assemblies, which can take many forms, are well known in the art and need not be further discussed for purposes of the present application.

It should also be noted that the roadway mechanism 14 illustrated in FIG. 1 includes a single endless belt 22 upon which the vehicle 13 is supported. As appreciated by those skilled in the art, aspects of the present invention can be applied to roadway mechanisms that comprise two or more belts used to support the vehicle 13 and/or are positioned under various portions or proximate to panels of the vehicle 13. All of the belts, if more than one is present, are driven by suitable motors and rollers, the details of which are well known, and not necessary for understanding aspects of the present invention.

Referring now to the vehicle restraint 9, in one form, the vehicle restraint 9 restrains and can control the position of the vehicle 13 on the belt(s) 22, and in particular, control a vertical position of the vehicle and/or measure loads or forces on the vehicle 13. The restraint 9 can have the ability to lift the vehicle 13 upwardly relative to the platform 16 or belt 22 so as to perform work upon the vehicle 13 such as to access the underside of the vehicle 13 to replace components. The restraint 9 should have as minimal effect on air flow around the vehicle 13 as possible during testing. As such supports 30 that extend from “stationary” portions of the platform 16 (relative to movement of the belt 22) on opposite sides of the vehicle 13 over portions of the belt 22 are provided. The supports 30 are axially (along their longitudinal length) rigid or stiff and generally aerodynamic (e.g. slender and/or streamlined in shape) to minimize airflow disturbance.

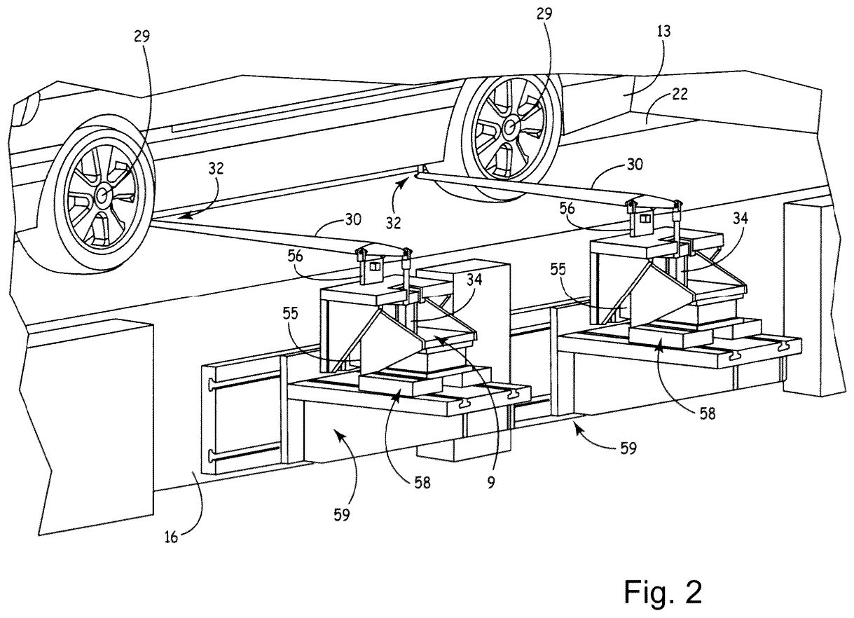

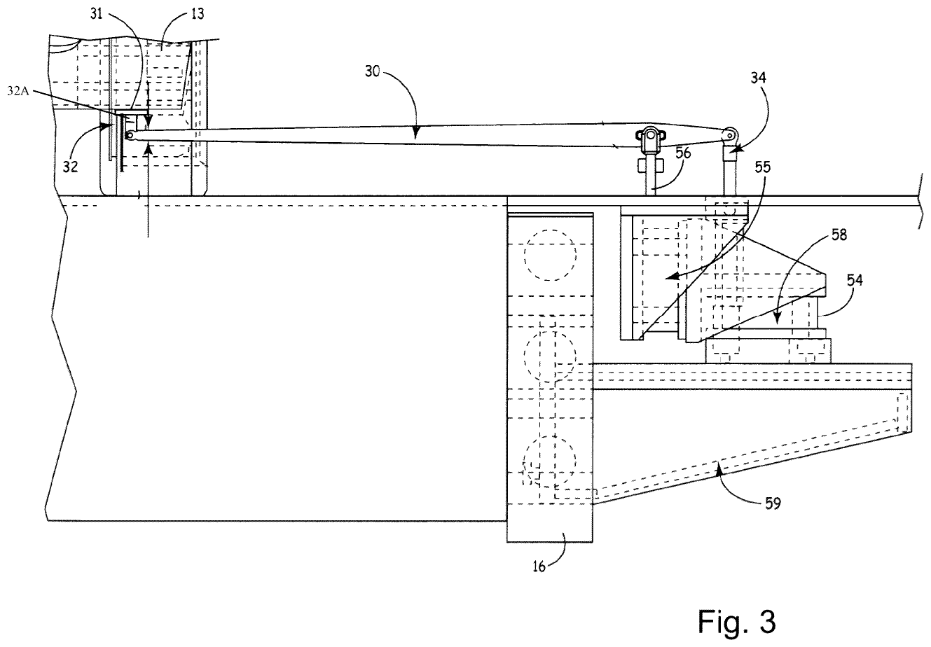

Referring to FIGS. 2 and 3, couplers 32 are coupled to attachment points 31 of the vehicle 13, which may already be available, or may require slight modification such as by providing suitable flanges, thereby allowing the vehicle to be rolled onto the belt 22 and quickly secured. In many instances, each coupler 32 includes an actuator 32A that can be selectively operated so as to operate a coupling to couple and decouple the coupler 32 to a portion of the attachment point 31 of the vehicle 13. The actuator 32A can comprise an electrical, pneumatic or hydraulic mechanism as is known in the art.

In general, each of couplers 32 is joined through each respective support 30 to an actuator assembly 34. The actuator assembly 34 allows a remote end of the support 30 to be positioned proximate the portion of the vehicle 13 to which the coupler 32 will be attached. If desired, selective control of each of the actuators 34, allows the operator to obtain desired characteristics of the vehicle 13 such as vehicle position, ride height, etc., which furthermore can be adjusted while the vehicle 13 is rolling on the belt 22. In addition, if desired, the actuators 34 can be controlled so as to lift the vehicle 13 completely off the belt 22.

In the embodiment illustrated, each support 30 is pivotally coupled to a support fixture 56 where an end of each support 30 remote from the vehicle 13 is coupled to the lift actuator 34. In view that each support pivots at or on a support fixture 56, it may be necessary to provide lateral compensation. In the embodiments illustrated in FIGS. 1-3, compensation is provided by a lateral positioner 58 that can carry the lift actuator 34 and support fixture 56 as well as a load cell 54 that measures horizontal loads (generally transverse and/or parallel to simulated vehicle motion) and a load cell 55 that measures vertical loads (generally orthogonal to simulated vehicle motion). The positioner 58 can take many forms as appreciated by those skilled in the art. Commonly, the positioner 58 includes two elements moving via a guide track under the control of an actuator with suitable sensors providing position information back to a controller. In a further embodiment, the lateral positioner 58 is also supported on platform 16 by a longitudinal positioner 59. Like the lateral positioner 58, the longitudinal positioner 59 can take many forms as appreciated by those skilled in the art. Commonly, the positioner 59 includes two elements moving via a guide track under the control of an actuator with suitable sensors providing position information back to the controller. The longitudinal positioner 59 allows longitudinal positioning of each corresponding support 30. If desired, as is known in the art, suitable couplers can be provided on the end of each support 30 to connect the support 30 to a wheel hub 29 (FIG. 2).

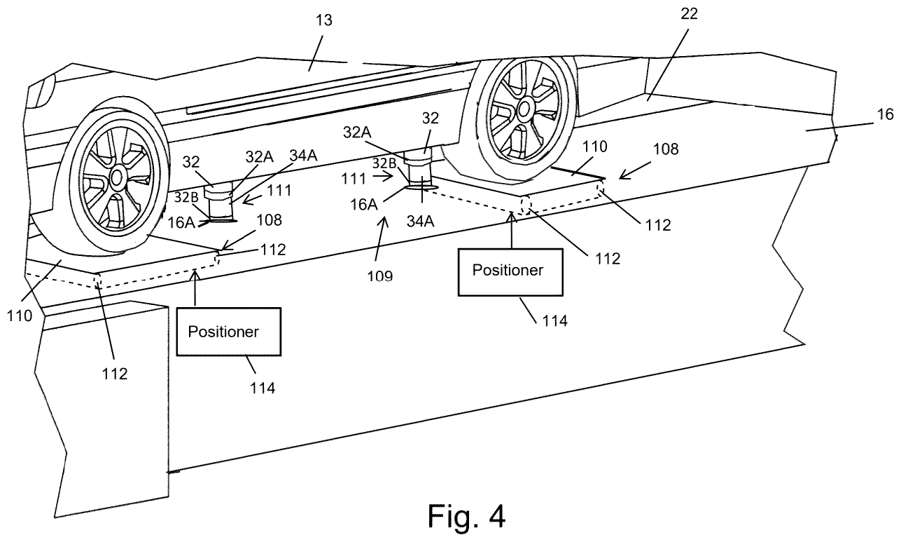

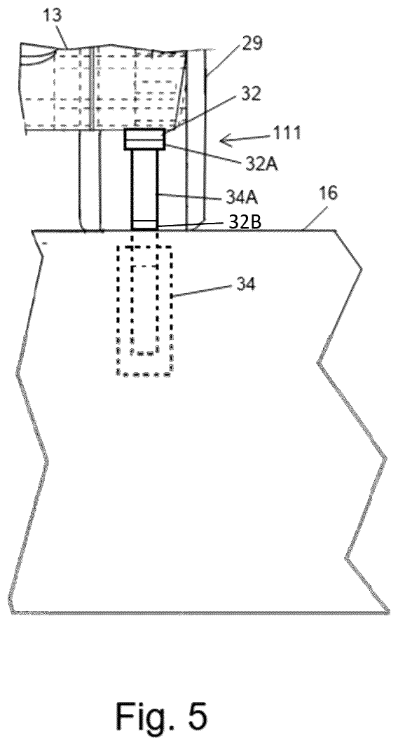

FIGS. 4-5 illustrate another embodiment of a restraint system 109 comprising spaced apart restraints 111 mounted to a support structure such as platform 16 for instance directly below the portion of the vehicle 13 to which it is coupled. In this embodiment, the roadway simulator 10 comprises a plurality of rotatable assemblies 108, wherein a separate rotatable assembly 108 is provided for each wheel of the vehicle 13. Each rotatable assembly 108 can comprise one or more or rollers in contact with each tire of the vehicle 13, while in another embodiment, each rotatable assembly 108 comprises an endless belt driven 110 by rollers 112 as is well known in the art. A center belt or endless member 22 can be disposed between the rotatable assemblies 108 and although not in contact with the vehicle 13 can simulate movement of the vehicle 13 over a center portion of a road. Each rotatable assembly 108 can be mounted so as to be stationary in a relative position with respect to the platform 16 albeit rotating each corresponding wheel 29 of the vehicle 13. However, in another embodiment, a positioner 114 (schematically illustrated) can be provided so as to support each rotatable assembly 108 while allowing the overall position of the rotatable assembly 108 to move in longitudinal, lateral and/or vertical directions, thus imparting forces and/or displacements to each wheel of the vehicle 13 so as to emulate travel over a road that is not always flat. Positioners 114 for rotatable assemblies 114 include suitable actuators and guide structures (similar to that of positioners 58 and 59) and are well known in the art.

Restraints 111 include the coupler 32, the actuator 32A and the actuator 34 herein directly coupled below the coupler to the platform 16, where an actuator rod 34A extends through an aperture 16A in the platform 16. Operation of the actuator 34 positions the coupler 32 against the vehicle 13 allowing the actuator 32A to be operated to couple or decouple the vehicle 13 to the platform 16. Preferably, the actuator 34 and coupler 32 are configured such that when fully retracted the coupler 32 is positioned at or below the platform 16 such that the vehicle 13 can travel over the restraints 111 without difficulty thereby allowing the vehicle 13 to be moved on and off the platform 16 when needed.

In a further embodiment, restraint 111 can include an additional actuator 32B spaced apart from actuator 32A, herein disposed closer to the platform 16. Operation of both actuators 32A and 32B so as to decouple the vehicle 13 from the actuator 34 would allow a large extent of the restraint 111 to fall away from both the vehicle 13 and the actuator 34 thus allowing the vehicle 13 to be moved without being inhibited by the restraint 111. With the addition of actuator 32B, the actuator 34 would not need to be operated so as to retract its actuator rod 34A into the aperture 16A and below the platform 16.

At this point, it should be noted that alternative restraint systems can be used and the present invention is not limited to the embodiments described above. Referring back to FIG. 1, in yet another restraint system, a restraint arm or support 120 includes a coupler 122 functionally similar to coupler 32 in that it can include an actuator 122A to selectively couple the coupler 122 to a front portion of the vehicle 13, while a similar support and coupler can be provided for a rear portion of the vehicle 13 if desired. Although illustrated as an arm, it should be noted the support can also be a cable, strap or the like extending forwardly that operates in tension to hold the position of the vehicle 13 on the simulator 10.

Likewise, a support 130 can be provided from above having a coupler 132 having an actuator 132A on an end thereof that is selectively coupled to an upper portion of the vehicle 134. A suitable positioner, not shown, can be coupled to the support 122, the support 130, or the end of the cable or strap, and include one or more actuators so as to allow positioning of the attached coupler and/or provide restraint but also allow some limited movement of the vehicle 13 on the simulator 10. If desired, additional actuators can be included in the supports 122 or 130, or other components of the restraint, in a manner like actuator 32B with actuator 32A, so that other portions of the restraint can break away when it is desired to remove the vehicle 13, again possibly avoiding the need to operate a positioning actuator of the restraint to move the restraint out of the way of the vehicle after operation of an actuator that decouples the restraint from the vehicle.

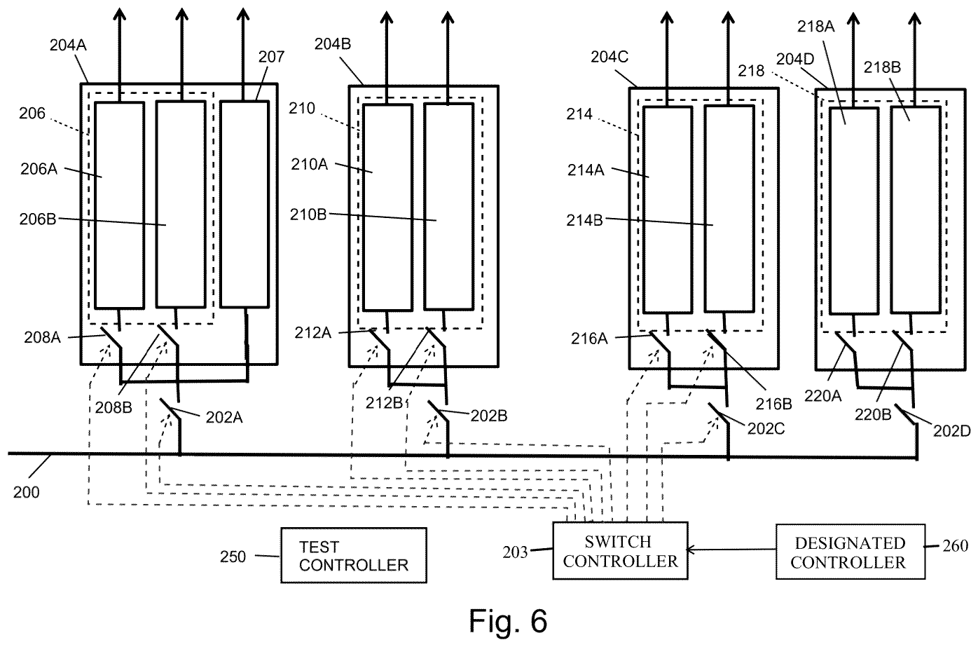

FIG. 6 schematically illustrates electrical cabinetry and power lines for supplying electrical power to various systems of the roadway simulator 10. In FIG. 6, electrical power is from a main power line 200 having switches 202A, 202B, 202C and 202D controlling electrical power to individual cabinets 204A, 204B, 204C and 204D containing circuity for various systems of the simulator 10, the switches 202A, 202B, 202C and 202D being schematically shown as operated from a switch controller 203. For instance, cabinet 204A includes circuity for actuators for any of the couplers described above. Generally, the circuitry comprises an actuator drive assembly 206 having an actuator control module 206A used to control the actuator(s) of the coupler(s) as well as an actuator electrical power supply 206B that provides electrical power to power the actuator(s) directly such when the actuator(s) is electrical in nature such as being a solenoid, linear or rotary electric actuator, or motor for a screw-type actuator. In alternative forms, the actuator electrical power supply 206B would supply electrical power to pneumatic or hydraulic pumps, if the actuator(s) is pneumatic or hydraulic. Each of the actuator control module 206A and the actuator electrical power supply 206B are selectively energized with a power control switch 208A and 208B. Again, FIG. 6 is schematic in that the actuator control module 206A and the actuator electrical power supply 206B are shown located in the same electrical cabinet, but this may not be the case if the power or voltage requirements require that the actuator control module 206A and the actuator electrical power supply 206B be located in separate cabinets. Nevertheless the actuator control module 206A and the actuator electrical power supply 206B are used together to operate the coupling actuator(s) e.g. 32A, 122A or 132A to which they are operably connected.

Similarly, cabinet 204B illustrates an actuator control module 210A and an actuator electrical power supply 210B of another actuator drive assembly 210 for actuators e.g. 34 used in positioning the support arms, rods, cables or straps. Each of the actuator control module 210A and the actuator electrical power supply 210B are selectively energized with a power control switch 212A and 212B. Again, FIG. 6 is schematic in that the actuator control module 210A and the actuator electrical power supply 210B are shown located in the same electrical cabinet, but this may not be the case if the power or voltage requirements require that the actuator control module 210A and the actuator electrical power supply 210B be located in separate cabinets nevertheless the actuator control module 210A and the actuator electrical power supply 210B are used together to operate the actuator(s) to which they are connected.

Likewise, cabinet 204C illustrates an positioner control module 214A and a positioner electrical power supply 214B of a positioner drive assembly 214 for any component of the simulator 10 that may need to be moved in order to remove the vehicle 13 from the simulator 10. For instance, such a positioner may be positioner 114 used to control the position of one the rotatable assemblies 108 such that rotatable assembly 108 can be positioned relative to the surface 16 so the vehicle 13 can be moved along the surface 16. The positioner could also be a drive assembly used to rotate the surface 16 if it comprises a turntable. The positioner control module 214A and the positioner electrical power supply 214B are selectively energized with a power control switch 216A and 216B. Again, FIG. 6 is schematic in that the positioner control module 214A and the positioner electrical power supply 214B are shown located in the same electrical cabinet, but this may not be the case if the power or voltage requirements require that the positioner control module 214A and the positioner electrical power supply 214B be located in separate cabinets nevertheless the positioner control module 214A and the positioner electrical power supply 214B are used together to operate the positioner to which they are connected.

Lastly, in the schematic illustration of FIG. 6, cabinet 204D illustrates a rotatable drive control module 218A and a rotatable drive electrical power supply 218B of a rotatable drive assembly 218 for a rotatable assembly 108 of the simulator 10. The rotatable drive control module 218A and the rotatable drive electrical power supply 214B are selectively energized with a power control switch 220A and 220B. Again, FIG. 6 is schematic in that the rotatable drive control module 218A and the rotatable drive electrical power supply 218B are shown located in the same electrical cabinet, but this may not be the case if the power or voltage requirements require that the rotatable drive control module 218A and the rotatable drive electrical power supply 218B be located in separate cabinets nevertheless the rotatable drive control module 218A and the rotatable drive electrical power supply 218B are used together to operate the rotatable drive to which they are connected.

All the switches 208A-208B, 212A-212B, 216A-216B and 220A-220B are schematically shown as operated by switch controller 203; however, a separate switch controller could be used separate from switch controller 203 if desired.

In normal operation, the vehicle 13 is positioned on the roadway simulator 10 and is coupled thereto with a restraint assembly such as any of the restraint assemblies, for example, 9 or 109 described above or similar such functioning restraint assemblies. A controller 250 (FIG. 6) is used to control the roadway simulator 10 as needed to conduct the desired test to be performed on the vehicle 13. (The test controller 250 is operably coupled to the control modules and power supplies described above wherein the control lines have been omitted to enhance understanding of other aspects shown. With respect to the electrical schematic of FIG. 6, the switches 202A-202D, 208A-208B, 212A-212B, 216A-216B and 220A-220B are closed as necessary to conduct the test. For instance, the rotatable drive assemblies 108 are operated to simulate desired speed of travel of the vehicle 13 along a road. If provided positioners 114 can impart forces or displacements to individual wheels of the vehicle 13 as desired. If located in a wind tunnel the wind tunnel fan can be operated to generate air flow upon the vehicle 13, and the turntable 16, if also provided, can change the angular position of the vehicle 13 with respect to the air flow 17.

However, it is possible that during a test or otherwise, it becomes necessary that the vehicle 13 needs to be removed from the simulator 10 such as when the vehicle 13 may be on fire and its presence on the simulator 10 could cause significant damage to the simulator 10. The electrical circuitry and switch control illustrate in FIG. 6 enables safe removal of the vehicle 13 from the simulator 10 when such a situation exists.

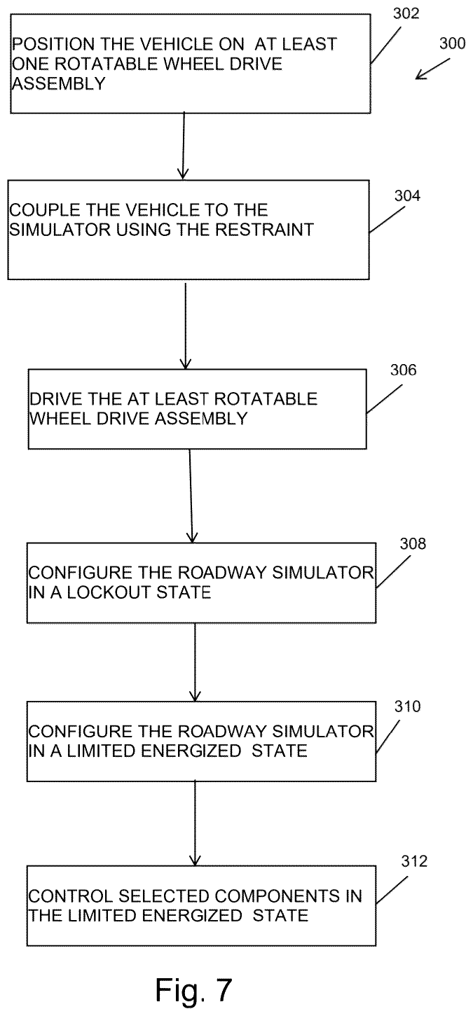

FIG. 7 illustrates a method 300 for testing a vehicle 13 on the roadway simulator 10 having at least one rotatable assembly 108 for rotating at least one wheel of the vehicle 13. The method 300 includes at step 302 positioning the vehicle 13 on the at least one rotatable assembly 108.

At step 304 a restraint e.g. 9, 109 is coupled to the vehicle 13 so as to limit longitudinal and/or lateral movement of the vehicle 13 on the at least one rotatable assembly 108. The coupling includes controlling the first actuator e.g. 34 to position and end of the restraint 9, 109 approximate a portion of the vehicle 13 and/or controlling an actuator e.g. 32A, 122A, 132A to couple the restraint to a portion of the vehicle 13.

At step 306 the at least one rotatable assembly 108 is driven so as to rotate the at least one wheel on the vehicle 13 during a normal test desired to be performed on the vehicle 13. Typically, this would include operating most if not all the desired sub-assemblies or mechanisms of the roadway simulator 10 provided, which includes powering all of the cabinets such as cabinets 204A-204D illustrated in FIG. 6 among many other that are not shown since they pertain to the normal operation of a test.

During operation of the test or typically in close proximity time to conducting a test, the operator becomes aware of a problem with the vehicle 13 under test requiring that it should be removed from the roadway simulator 10 as soon as possible. Typically, the operator will initiate an emergency stop or the like through test controller 250 or other suitable switch, which removes most of if not all electrical power being provided to the roadway simulator 10 through the electrical cabinets 204A-204D schematically illustrated in FIG. 6. For instance, the emergency stop will commonly cause many if not all of the control switches 202A-202D and/or switches 208A-208B, 212A-212B, 216A-216B and 220A-220B to open so as to remove electrical power from the cabinets 204A-204D. As used herein the roadway simulator 10 is now in a “lockout state” wherein power is isolated from the components of the roadway simulator 10 and thus with such power removed inhibits operation for conducting a test. The “lockout state” includes isolating electrical power from any and all rotatable drive assemblies 218 for the rotatable assemblies 108. The “lockout state” also isolates electrical power from actuator and drive assemblies 208, 206 for the actuator 34 and/or the actuator 32A, 32B 122A, 132A. The “lockout state” typically would also operate the control switches 220A-220B for the rotatable drive assembly 218.

As indicated above, in this situation there is a desire to remove the vehicle 13 from the roadway simulator 10 and in order to do so an aspect of the present invention allows selective energization of those components needed to decouple the vehicle 13 from the roadway simulator 10. At step 310 the roadway simulator 10 is configured in a “limited energized state”, which as used herein entails that testing of the vehicle 13 is inhibited due to continued isolation of electrical power to the rotatable drive assembly 218 and wherein electrical power is restored to the actuator drive assembly 206, 210 for the actuator 34 and/or the actuator 32A, 32B 122A, 132A. The “limited energized state” is achieved by providing control signals to operate each of the switches of the control switches 208A-208B, 212A-212B and 216A-216B as needed. However, again, power is not provided to many other components of the road simulator 10 that are not needed to remove the vehicle 13 from the simulator 10 such as the rotatable drive assembly 218.

At this point it should be noted that it is not necessary that the simulator include all the switches 208A-208B, 212A-212B, 216A-216B and 220A-220B as illustrated in order to achieve the lockout state and the limited energized state. If desired, these states can be achieved by control of switches 202A-202D for each of the cabinets 204A-204D, where a single control switch could also selectively provide power to two or more cabinets. To achieve the limited energized state, switches 202A-202C are selectively operated to provide power to the control modules and power supplies needed for operation of the actuators so as to release the restraints and move them such that the vehicle 13 can be moved. Sometimes a cabinet may include other modules, power supplies, circuitry of the like such as indicated at 207 in FIG. 6 that might be energized along with the control modules and power supplies needed for operation of the actuators so as to release the restraints and move them such that the vehicle 13 can be moved, however, this is typically not a problem since energization will only be temporary to the extent needed to remove the vehicle 13.

At step 312, with the simulator 10 powered in the limited energized state, the actuator e.g. 34 is controlled to position the end of the restraint remote from the vehicle 13 to allow the vehicle 13 to be removed from the at least one rotatable assembly 108 and/or the actuator 32A, 32B 122A, 132A is controlled so as to decouple the restraint from the portion of the vehicle 13.

FIG. 6 illustrates a designated control or controller 260 that is operated by the operator to place the simulator in the limited energized state where at least the actuator drive assemblies 206 and/or 210 are energized such that the actuators powered and controlled thereby can be operated as desired to decouple the vehicle and/or reposition the restraints out of the way such that vehicle 13 can be removed from the simulator 10. In one embodiment, the designated control 260 is remote from a user interface for operating the roadway simulator to perform the test of the vehicle by controlling the at least one rotatable assembly such that inadvertent operation of the designated control 260 is inhibited. For instance, the designated control 260 can be located on a separate panel from the user interface for the controller 250 used to conduct a test. The designated control 260 could entail use of a key to operate the control 260 or otherwise gain access to it.

In another embodiment, the designated control 260 can be part of the user interface used for conducting a test, but access to the designated control 260 could possibly entail switching to a different screen rendered on the user interface, or otherwise require certain operation of buttons or the like on the rendered screen to gain access to it.

In FIG. 6, the designated controller 260 is operably coupled to the switch controller 203 so as to provide command signals to operate switches 208A-208B and 212A-212B as needed. However, it should be understood that designated controller 260 may be operably connected to switches 208A-208B and 212A-212B without using switch controller 203 if desired.

Detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in expectedly any appropriately detailed structure. In particular, features presented and described in separate dependent claims may be applied in combination and any advantageous combination of such claims are herewith disclosed.

Further, the terms and phrases used herein are not intended to be limiting, but rather to provide an understandable description of the invention. The terms “a” or “an”, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly.

Aspects of the invention being thus described it is apparent that the same may be varied in many ways. Such variations are not to be regarded as a departure from the spirit and scope of the invention, and all such modifications as would be apparent to one skilled in the art are intended to be included within the scope of the following claims.

What is claimed is:

1. A method for testing a vehicle on a roadway simulator having at least one rotatable assembly for rotating at least one wheel of the vehicle, the method comprising:
positioning the vehicle on the at least one rotatable assembly;
coupling a restraint to the vehicle so as to limit longitudinal and/or lateral movement of the vehicle on the at least one rotatable assembly, wherein coupling includes controlling a first actuator to position an end of the restraint proximate a portion of the vehicle and/or controlling a second actuator to couple the restraint to the portion of the vehicle;
driving the at least one rotatable assembly to rotate the at least one wheel on the vehicle;
configuring the roadway simulator in a lockout state wherein power is isolated from roadway simulator that inhibits operation for conducting a test including isolating electrical power from a rotatable drive assembly for the at least one rotatable assembly and for isolating electrical power from an actuator drive assembly for the first actuator and/or the second actuator;
configuring the roadway simulator in a limited energized state wherein testing of the vehicle is inhibited due to continued isolation of electrical power to the rotatable drive assembly and wherein electrical power is restored to the actuator drive assembly for the first actuator and/or the second actuator; and
controlling the first actuator to position the end of the restraint remote from the vehicle to allow the vehicle to be removed the at least one rotatable assembly and/or controlling the second actuator to decouple the restraint from the portion of the vehicle.

2. The method of claim 1, wherein the roadway simulator includes a designated control for configuring the roadway simulator in the limited energized state, and wherein configuring the roadway simulator in the limited energization state includes providing a control signal from the designated control to energize circuitry for the first and/or second actuator.

3. The method of claim 2, wherein the designated control is remote from a user interface for operating the roadway simulator to perform the test of the vehicle by controlling the at least one rotatable assembly.

4. The method of claim 2, wherein the designated control is part of a user interface for operating the roadway simulator to perform the test of the vehicle by controlling the at least one rotatable assembly.

5. The method of claim 2, wherein providing the control signal includes providing a control signal to a first controlled switch to operate the first controlled switch to provide electrical power to the actuator drive assembly for the first actuator and/or the second actuator.

6. The method of claim 5, wherein designated control is not configured to operate a switch that provides electrical power to the rotatable drive assembly.

7. The method of claim 2, wherein the actuator drive assembly comprises an actuator electrical power supply providing power to the first actuator and/or the second actuator and an actuator control module connected to the actuator electrical power supply and configured to control operation of the actuator electrical power supply.

8. The method of claim 7, wherein a power supply switch selectively provides electrical power to the actuator electrical power supply, and a control module switch selectively provides electrical power to the actuator control module, and wherein providing the control signal operates the power supply switch to provide electrical power to the actuator electrical power supply, and operates the control module switch to provide electrical power to the actuator control module.

9. The method of claim 8, wherein power supply switch selectively provides electrical power to another portion of the roadway simulator different than the actuator electrical power supply, the another portion of the roadway simulator having another control module different than the actuator control module, wherein providing the control signal does not provide electrical power to the another control module.

10. The method of claim 2, wherein roadway simulator comprises a positioner for controlling a position of an element of the roadway simulator, and wherein configuring the roadway simulator in the lockout state comprises isolating electrical power to a positioner drive assembly of the positioner, and wherein configuring the roadway simulator in the limited energized state, comprises restoring electrical power to the positioner drive assembly.

11. The method of claim 10, wherein the positioner positions the element in a selected position to allow removal of the vehicle from the roadway simulator.

12. The method of claim 11, wherein the roadway simulator comprises a turntable supporting the vehicle in selected angular positions, and the positioner drive assembly rotates the turntable.

13. The method of claim 11, wherein the positioner is coupled to the at least one rotatable assembly.

14. The method of claim 11, wherein the positioner drive assembly comprises a positioner electrical power supply providing power to the positioner and a positioner control module connected to the positioner electrical power supply and configured to control operation of the positioner electrical power supply.

15. The method of claim 14, wherein a positioner power supply switch selectively provides electrical power to the positioner electrical power supply, and a positioner control module switch selectively provides electrical power to the positioner control module, and wherein providing the control signal operates the positioner power supply switch to provide electrical power to the positioner electrical power supply, and operates the positioner control module switch to provide electrical power to the positioner control module.

16. The method of claim 1, wherein coupling the restraint to the vehicle comprises coupling the restraint to a side portion of the vehicle, or to an end portion of the vehicle, or to an upper portion of the vehicle.

17. The method of claim 1, wherein the first actuator adjusts a position of the end of the restraint, and the second actuator operates a coupler that couples the restraint to the vehicle.

18. The method of claim 1, wherein the at least one rotatable assembly comprises a single belt supporting and rotatably driving each wheel of the vehicle, or each separate rotatable assembly rotatably driving at least one wheel of the vehicle, each separate rotatable assembly rotatably driving one wheel of the vehicle.

19. A roadway simulator comprising:
at least one rotatable assembly for rotating at least one wheel of a vehicle;
a restraint couplable to a vehicle so as to limit longitudinal and/or lateral movement of the vehicle on the at least one rotatable assembly, wherein the restraint includes a first actuator to position an end of the restraint proximate a portion of the vehicle and/or a second actuator to couple the restraint to the portion of the vehicle;
a controller operable to configure the roadway simulator in a lockout state wherein power is isolated from roadway simulator that inhibits operation for conducting a test including isolating electrical power from a rotatable drive assembly for the at least one rotatable assembly and for isolating electrical power from an actuator drive assembly for the first actuator and/or the second actuator, and operable to configure the roadway simulator in a limited energized state wherein testing of the vehicle is inhibited due to continued isolation of electrical power to the rotatable drive assembly and wherein electrical power is restored to the actuator drive assembly for the first actuator and/or the second actuator.

20. The roadway simulator of claim 19, further comprising a designated control for configuring the roadway simulator in the limited energized state, and wherein the designated control provides a control signal to energize circuitry for the first and/or second actuator.

21. The roadway simulator of claim 20, wherein the designated control is remote from a user interface for operating the roadway simulator to perform the test of the vehicle by controlling the at least one rotatable assembly.

22. The roadway simulator of claim 20, wherein the designated control is part of a user interface for operating the roadway simulator to perform the test of the vehicle by controlling the at least one rotatable assembly.
